(19) United States
(12) Patent Application Publication
(10) Pub. No.: US 2003/0086458 A1
(43) Pub. Date: May 8, 2003

(54) Semiconductor laser including N-doped quaternary layer

(76) Inventor: Kenneth L Bacher, Macungie, PA (US)

Correspondence Address: William H Murray, Duane Morris & Heckscher LLP, 4200 One Liberty Place, Philadelphia, PA, 19103-7396, US

(21) Appl. No.: 09/495,988

(22) Filed: Feb. 1, 2000

(51) Int. Cl. H01S 5/00

(52) U.S. Cl. 372/45

(57) ABSTRACT

A semiconductor laser including a substrate layer, an n-doped quaternary layer disposed on the substrate layer, a quantum well layer disposed on the quaternary layer, and a cladding layer disposed on the quantum well layer. The structure of the laser creates an optical mode which is substantially more circular, and thus increases the efficiency of the laser when coupling to an optical fiber.

### FIELD OF THE INVENTION

The present invention relates to the field of semiconductor lasers.

### DESCRIPTION OF THE RELATED ART

Semiconductor lasers are well known, and have found a variety of different applications, from compact disk players to optical fiber communication systems.

As those skilled in the art know, semiconductor lasers generally have an output beam of elliptical cross section and considerable spread in at least one direction, typically the vertical direction (i.e., the direction that is perpendicular both to the longitudinal axis of the laser and to the layer structure of the laser). This beam spread is a disadvantage, at least for applications that require coupling of the laser output beam into the core of an optical fiber, since it typically results in considerable coupling loss due to the elliptical shape of the beam and the substantially circular shape of the optical fiber. Thus, it would be highly desirable to have available semiconductor lasers that have low beam divergence.

FIG. 1 shows a conventional semiconductor laser structure 10. The laser structure 10 includes a substrate layer 20 of n-doped Indium Phosphide (InP) on which is disposed a first cladding layer 30 of n-doped InP. A first confinement layer 40 is disposed on the first cladding layer 30. The first confinement layer 40 may include one or more layers of Indium Gallium Arsenide Phosphide (InGaAsP). A quantum well layer 50 is disposed on the first confinement layer 40. As shown in FIG. 1, the quantum well layer 50 may include one or more quantum wells 51 (i.e. layers of InGaAsP) separated by spacer layers 52, also made of InGaAsP, but with a different composition than the quantum wells 51. As is well known in the art, the quantum wells 51 produce radiation which emanates therefrom when the quantum wells are coupled to a suitable current source and energized. A second confinement layer 60, including one or more layers of InGaAsP is disposed on top of the quantum well layer 50. A p-type cladding layer 70 of InP is disposed on the second confinement layer 60. Finally, a cap layer 80 of InGaAs is disposed on the cladding layer 70.

In operation, the quantum well layer 50 produces radiation (when it is supplied with a current) which is emitted outwardly in a specified pattern. As stated above, the radiation pattern is typically of elliptical cross section with significant spreading in the vertical direction, corresponding to the tighter confinement of the optical fields within the laser in this direction. FIG. 2 shows a typical optical field pattern 15 within the laser structure 10 shown in FIG. 1. As can be seen, the optical field pattern 15 of the laser structure 10 spreads less in the vertical direction, and more in the horizontal direction, leading to a more divergent output radiation pattern in the vertical direction. The spreading of the radiation pattern in the vertical direction (and the resultant spreading of the optical field pattern in the horizontal direction) causes significant losses to occur when coupling the laser structure 10 to a substantially circular device, such as an optical fiber. In, particular due to the substantially elliptical shape of the radiation pattern and the substantially circular shape of the optical fiber, not all of the radiation produced by the laser structure 10 is transferred to the optical fiber.

Therefore, there is currently a need for a semiconductor laser which has low beam divergence, that is to say, a laser whose radiation pattern is less elliptical.

### SUMMARY OF THE INVENTION

The present invention is a semiconductor laser including a substrate layer, an n-doped quaternary layer disposed above the substrate layer, a quantum well layer disposed above the quaternary layer and, a cladding layer disposed above the quantum well layer.

The above and other advantages and features of the present invention will be better understood from the following detailed description of the preferred embodiments of the invention which is provided in connection with the accompanying drawings.

### BRIEF DESCRIPTION OF THE DRAWINGS

FIG. 1 shows a conventional semiconductor laser structure.

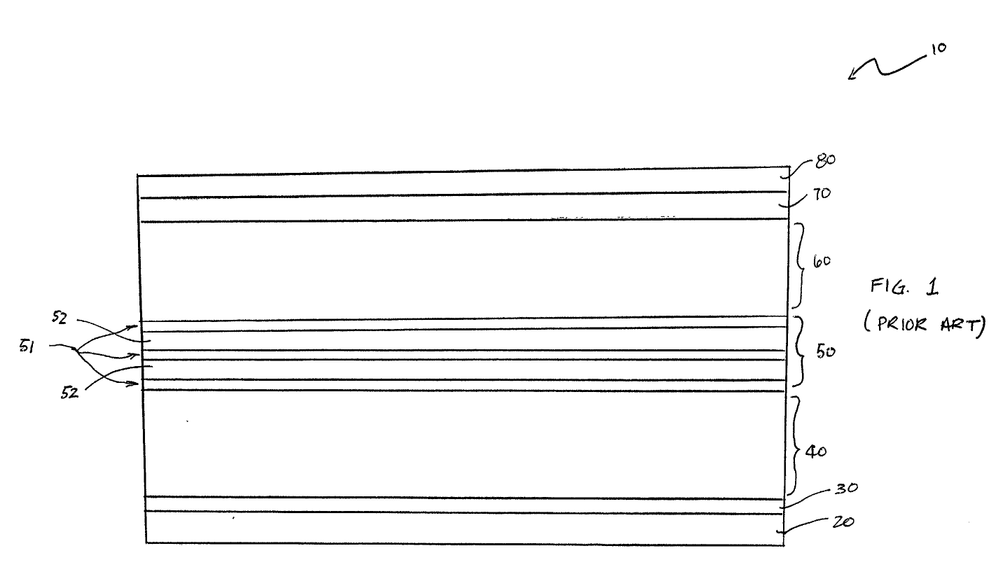

FIG. 2 shows a radiation pattern for the semiconductor laser structure shown in FIG. 1.

FIG. 3 shows a semiconductor laser structure according to an exemplary embodiment of the present invention.

FIG. 4 shows a radiation pattern for the semiconductor laser structure shown in FIG. 3.

FIG. 5 is a schematic diagram showing an optical fiber communication system including a laser structure according to the exemplary embodiment of the present invention.

### DETAILED DESCRIPTION

The present invention comprises a semiconductor laser which provides efficient coupling to an optical fiber and maximum power output. The radiation pattern of the semiconductor laser is altered by disposing an n-doped quaternary layer (i.e., a layer which includes at least four elements, e.g., InGaAsP) between a substrate layer and a quantum well of the laser. The n-doped quaternary layer allows radiation from the quantum well to permeate more into the n-doped quaternary layer and less into a p-doped cladding layer disposed adjacent to the quantum well. The thickness of the n-doped quaternary layer directly controls the radiation pattern. The composition of the quaternary material is preferably chosen to be lattice-matched to the substrate material, but to have a slightly higher index of refraction than the p-type cladding layer material. The higher index of refraction causes the optical mode (radiation pattern) to be less confined by the n-doped quaternary layer than the p-doped layer. As a result, the mode penetrates less into the p-doped layer and more into the n-doped quaternary layer where losses due to free carrier absorption are much lower. The n-doped quaternary layer should be made sufficiently thick to prevent increased confinement of the optical mode which would result in a wider (i.e. more vertical) radiation pattern. The thickness of the n-doped quaternary layer should be increased with the index of refraction of the material of the quaternary layer. For example, for a quaternary material with a bandgap of 1.24 electron-Volts (eV), the quaternary layer should be greater than 2 microns. For lower bandgaps, the quaternary layer should be of a lesser thickness (e.g. less than 2 microns).

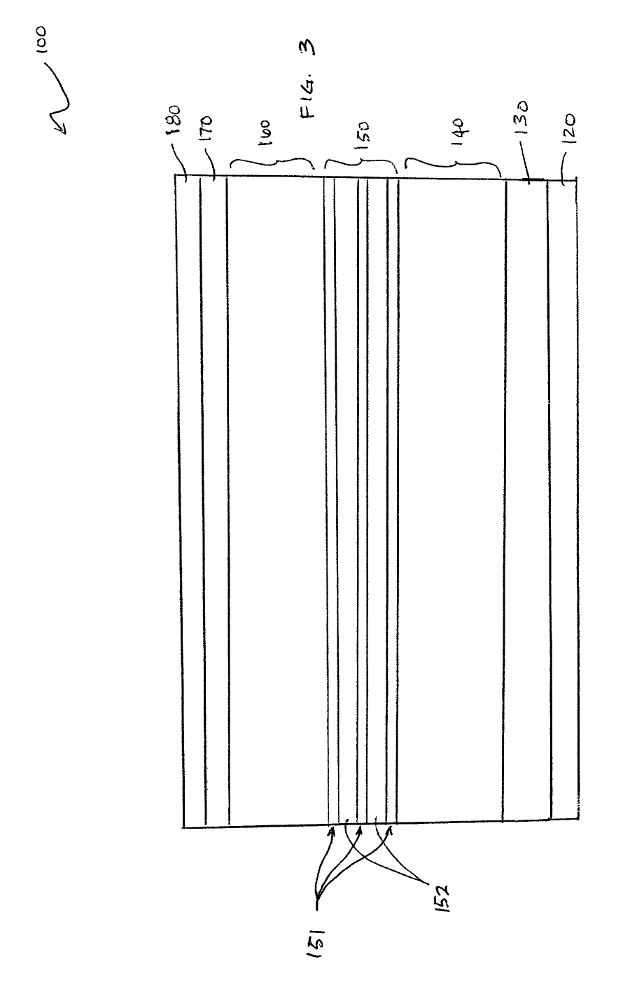

Referring to FIG. 3, there is shown a semiconductor laser structure 100 according to an exemplary embodiment of the present invention. The laser structure 100 includes a substrate layer 120, preferably of n-doped Indium Phosphide (InP), on which is disposed an n-doped quaternary layer 130. As stated above, the n-doped quaternary layer is preferably between 1-2.5 microns thick, and has a higher index of refraction than the p-type cladding layer 170. The n-doped quaternary layer may be formed of any quaternary material, however, Indium Gallium Arsenide Phosphide (InGaAsP) is preferred. Indium Aluminum Gallium Arsenide (InAlGaAs) may also be used for the quaternary layer 130. A first confinement layer 140 is disposed on the n-doped quaternary layer 130. The first confinement layer 140 may include one or more layers of Indium Gallium Arsenide Phosphide (InGaAsP). A quantum well layer 150 is disposed on the first confinement layer 140. The quantum well layer 150 may include one or more quantum wells 151 (e.g., layers of InGaAsP separated by spacer layers 152, preferably of InGaAsP. A second confinement layer 160, including one or more layers of InGaAsP is disposed on top of the quantum well layer 150. A p-type cladding layer 170, preferably of p-doped InP, is disposed on the second confinement layer 160. Finally, a cap layer 180 (of, for example p-doped InGaAs) is disposed on the p-type cladding layer 170.

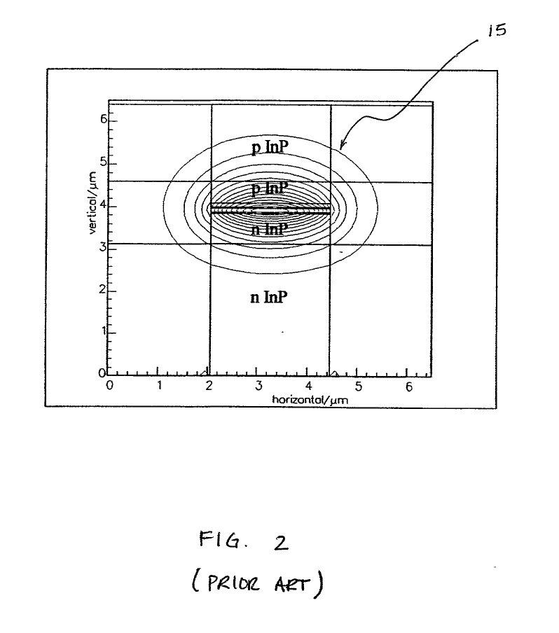

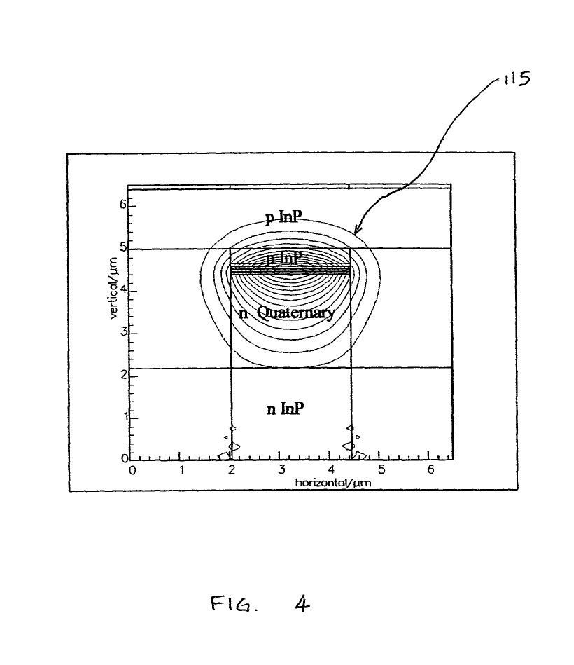

In operation, the quantum well layer 150 produces radiation (when it is supplied with a current) which is emitted outwardly in a specified pattern. The divergence of this radiation pattern is determined by the optical field pattern within the laser. FIG. 4 shows an optical field pattern 115 for the laser structure 100 shown in FIG. 3. As can be seen, the optical field pattern 115 of the laser structure 100 is less elliptical and more circular in shape than the optical field pattern 15 of conventional laser structure 10 shown in FIG. 2. This is because the addition of the n-doped quaternary layer 130 allows the optical field from the quantum wells 151 to permeate more into the quaternary layer 130 than the optical field 15 in the conventional laser structure 10 permeates into the cladding layer 30. The reduced confinement of the optical field within the laser structure causes less divergence of the resulting radiation pattern which forms outside the laser structure.

The increased permeation of the optical field into the quaternary layer 130 also reduces the permeation of the optical field into the p-type cladding layer 170 and cap layer 180. Optical losses that occur within the laser structure are significantly reduced by the transfer of the optical mode from the layers 170, 180 to the n-doped quaternary layer 130, resulting in increased optical power output. In addition, due to the more circular radiation pattern (resulting from the more circular optical field pattern within the laser structure 100), a greater percentage of the output radiation can be coupled from the laser to an optical fiber.

By making the n-doped quaternary layer 130 thick enough, and by adjusting the thickness of the separate confinement layers 140, 160 appropriately, one can obtain reduced optical loss while at the same time improving optical coupling. Thus, the exemplary laser structure provides a more efficient laser, whereby an increased amount of light radiation is gained without an increase in current or power.

Further, since the optical field permeates less into the p-type cladding layer 170 of the laser structure 100 than into the p-type cladding layer 70 of the conventional laser structure 10, the p-type cladding layer can be made thinner without degrading optical performance. Because p-type material is more resistive then n-type material, reducing the thickness of the p-type cladding layer 170 will also reduce the series resistance of the laser structure 100, thereby decreasing the electrical losses, and further increasing the efficiency of the laser structure. The reduction in thickness of the p-type cladding layer 170 also provides the additional benefit of reduced thermal impedance. In particular, since the second p-doped cap layer 180 is coupled to a heat sink (not shown) when the laser 100 is operated, the thinner the p-type cladding layer 170, the more heat that is dissipated by the heat sink. By dissipating more heat, the laser 100 can be operated at higher temperatures (i.e. at higher powers for longer periods), thereby improving performance of the laser.

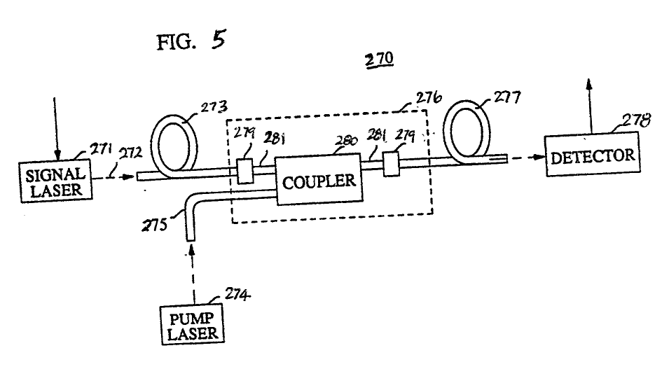

FIG. 5 schematically depicts an optical fiber communication system 270 including a laser structure according to the exemplary embodiment of the present invention. A signal laser 271 emits signal radiation 272 which is coupled into standard transmission fiber 273 and transmitted therethrough to fiber amplifier 276. Pump laser 274 emits pump radiation of an appropriate wavelength (e.g., 1.48 μm) which is transmitted by means of a short length of fiber 275 into fiber amplifier 276. The fiber amplifier 276 preferably includes a rare-earth doped fiber 281 coupled, by means of conventional connectors 279, to transmission fiber 273 and to transmission fiber 277. The fiber amplifier 276 also includes a coupler 280 to couple the pump radiation from fiber 275 to fiber 281. Signal radiation is amplified in the fiber amplifier 276 in a known manner, and is then transmitted through transmission fiber 277 to detector 278. The laser structure 100 described above with reference to FIG. 3 may serve as either the signal laser 271 or the pump laser 274 of the optical fiber communication system 270.

Although the invention has been described in terms of exemplary embodiments, it is not limited thereto. Rather, the appended claims should be construed broadly, to include other variants and embodiments of the invention which may be made by those skilled in the art without departing from the scope and range of equivalents of the invention.

What is claimed is:

1. A semiconductor laser comprising:
a substrate layer;
an n-doped quaternary layer disposed above the substrate layer;
a quantum well layer disposed above the quaternary layer; and,
a cladding layer disposed above the quantum well layer.

2. The semiconductor laser of claim 1, further comprising:
at least one first confinement layer disposed between the quaternary layer and the quantum well layer.

3. The semiconductor laser of claim 2, further comprising:
at least one second confinement layer disposed between the quantum well layer and the cladding layer.

4. The semiconductor laser of claim 1, further comprising:
a cap layer disposed above the cladding layer.

5. The semiconductor laser of claim 1, wherein the substrate layer comprises n-doped Indium Phosphide.

6. The semiconductor laser of claim 1, wherein the n-doped quaternary layer comprises Indium Gallium Arsenide Phosphide.

7. The semiconductor laser of claim 1, wherein n-doped quaternary layer is approximately 1-2.5 microns thick.

8. The semiconductor laser of claim 1, wherein at least one portion of the quantum well layer comprises Indium Gallium Arsenide Phosphide.

9. The semiconductor laser of claim 1, wherein the cladding layer comprises p-doped Indium Phosphide.

10. The semiconductor laser of claim 1, further comprising:
a current source coupled to said semiconductor laser for causing the laser to emit radiation in a specified pattern.

11. The semiconductor laser of claim 10, wherein the radiation pattern extends further in a direction towards the n-doped quaternary layer.

12. An optical fiber communication system comprising:
an optical fiber;
a semiconductor laser including a substrate layer; an n-doped quaternary layer disposed above the substrate layer; a quantum well layer disposed above the quaternary layer; and, a cladding layer disposed above the quantum well layer.
a current source coupled to said semiconductor laser for causing the laser to emit radiation in a specified pattern; and,
means for coupling at least a portion of said radiation into the optical fiber.

13. The optical fiber communication system of claim 12, further comprising:
at least one first confinement layer disposed between the quaternary layer and the quantum well layer.

14. The optical fiber communication system of claim 12, further comprising:
at least one second confinement layer disposed between the quantum well layer and the cladding layer.

15. The optical fiber communication system of claim 12, further comprising:
a cap layer disposed above the cladding layer.

16. The optical fiber communication system of claim 12, wherein the substrate layer comprises n-doped Indium Phosphide.

17. The optical fiber communication system of claim 12, wherein the n-doped quaternary layer comprises Indium Gallium Arsenide Phosphide.

18. The optical fiber communication system of claim 12, wherein n-doped quaternary layer is approximately 1-2.5 microns thick.

19. The optical fiber communication system of claim 12, wherein at least one portion of the quantum well layer comprises Indium Gallium Arsenide Phosphide.

20. The optical fiber communication system of claim 12, wherein the cladding layer comprises p-doped Indium Phosphide.

21. The optical fiber communication system of claim 12, wherein the radiation pattern extends further in a direction towards the n-doped quaternary layer.

22. A method of improving optical coupling of a semiconductor laser to an optical fiber, the improvement comprising the step of:
providing a n-doped quaternary layer between a substrate layer and a quantum well layer of the semiconductor laser.

23. The method of claim 22, wherein the n-doped quaternary layer comprises a layer of Indium Gallium Arsenide Phosphide.

24. The method of claim 22, wherein the substrate layer comprises n-doped Indium Phosphide and the quantum well layer includes at least one layer of Indium Gallium Arsenide Phosphide.
